(19) United States
(12) Patent Application Publication
(10) Pub. No.: US 2025/0169289 A1
(43) Pub. Date: May 22, 2025

(54) DISPLAY DEVICE AND METHOD OF MANUFACTURING DISPLAY DEVICE

(71) Applicant: Samsung Display Co., LTD., Yongin-si (KR)

(72) Inventors: Jae Been LEE, Yongin-si (KR); Ye Hwan CHOI, Yongin-si (KR); Ju Won YOON, Yongin-si (KR)

(21) Appl. No.: 18/815,749

(22) Filed: Aug. 26, 2024

(30) Foreign Application Priority Data
Nov. 20, 2023 (KR) 10-2023-0161375

(51) Int. Cl. H10K 59/122; H10K 59/12; H10K 59/80

(52) U.S. Cl. CPC H10K 59/122; H10K 59/1201; H10K 59/80515

(57) ABSTRACT

A display device and a method of manufacturing the same are provided. The display device includes: a pixel-circuit layer including a pixel circuit on a substrate; and a light-emitting-element layer on the pixel-circuit layer, wherein the light-emitting-element layer includes: an anode electrode; a pixel defining layer covering at least a portion of the anode electrode, the pixel defining layer forming a pixel defining opening exposing at least a portion of the anode electrode; a light emitting structure electrically connected to the anode electrode; and a cathode electrode electrically connected to the light emitting structure, wherein the pixel defining layer includes a rounded upper surface having a rounded corner, the rounded upper surface including an inclined side surface facing the pixel defining opening, and wherein an angle between the inclined side surface and a top surface of the anode electrode is in a range of 15 degrees to 45 degrees.

### CROSS-REFERENCE TO RELATED APPLICATION

The present application claims priority to and the benefit of Korean Patent Application No. 10-2023-0161375, filed on Nov. 20, 2023, in the Korean Intellectual Property Office, the entire disclosure of which is incorporated herein by reference.

### BACKGROUND

### 1. Field

Aspects of some embodiments of the present disclosure relate to a display device and a method of manufacturing a display device.

### 2. Description of the Related Art

Recently, as interest in information displays is increased, research and development of display devices have been continuously conducted.

A display device may include sub-pixels each including an organic light emitting diode (OLED). The OLED is an active light emitting display element, may have a relatively wide viewing angle and may have relatively good contrast, may be capable of being driven at a relatively low voltage, may be relatively lightweight and thin, and may have a relatively high response speed.

The OLED may include a hole transport part, an electron transport part, and a light emitting layer between the hole transport part and the electron transport part. Holes provided from the hole transport part and electrons provided from the electron transport part may be recombined in the light emitting layer, thereby generating excitons. When the generated excitons are changed from an excited state to a ground state, light may be generated.

In order to emit light, the OLED may include a cathode electrode configured to provide electrons. The cathode electrode may be configured as a common electrode of each of different sub-pixels. In order for the cathode electrode to supply a cathode signal suitable for each OLED, it is necessary for the cathode electrode to be appropriately patterned in overall areas in which the sub-pixels are formed.

The above information disclosed in this Background section is only for enhancement of understanding of the background and therefore the information discussed in this Background section does not necessarily constitute prior art.

### SUMMARY

Aspects of some embodiments include a display device and a method of manufacturing a display device, which can provide a detailed cathode electrode structure, thereby reducing a risk such as a voltage drop.

Aspects of some embodiments also include a display device and a method of manufacturing a display device, which can improve process convenience.

Aspects of some embodiments also include a display device and a method of manufacturing a display device, which can reduce a risk due to a leakage current or the like, thereby relatively improving display quality.

According to some embodiments of the present disclosure, a display device includes: a pixel-circuit layer including a pixel circuit on a substrate; and a light-emitting-element layer on the pixel-circuit layer, wherein the light-emitting-element layer includes: an anode electrode; a pixel defining layer covering at least a portion of the anode electrode, the pixel defining layer forming a pixel defining opening exposing at least a portion of the anode electrode; a light emitting structure electrically connected to the anode electrode; and a cathode electrode electrically connected to the light emitting structure, wherein the pixel defining layer includes a rounded upper surface having a rounded corner, the rounded upper surface including an inclined side surface facing the pixel defining opening, and wherein an angle between the inclined side surface and a top surface of the anode electrode is in a range of 15 degrees to 45 degrees.

According to some embodiments, the display device may further include a planarization layer on the pixel-circuit layer. According to some embodiments, the pixel defining layer may be continuously on the planarization layer and the anode electrode. According to some embodiments, the rounded upper surface may be defined at a portion of the pixel defining layer covering the anode electrode.

According to some embodiments, the rounded upper surface may overlap with an edge of the anode electrode in a plan view, and be in contact with the light emitting structure.

According to some embodiments, the pixel defining layer may include an undercut structure.

According to some embodiments, the display device may further include: a lower cover layer between the anode electrode and the pixel defining layer; and a cavity adjacent to the lower cover layer, the cavity being surrounded by the pixel defining layer, the light emitting structure, and the anode electrode.

According to some embodiments, the lower cover layer may include a metal material. According to some embodiments, the cavity may be directly adjacent to the light emitting structure.

According to some embodiments, the substrate may include a silicon wafer substrate. According to some embodiments, the light emitting structure may include a hole transport part adjacent to the anode electrode, a light emitting layer on the hole transport part, and an electron transport part which is on the light emitting layer and is adjacent to the cathode electrode.

According to some embodiments, the anode electrode may include a first anode electrode layer including titanium, a second anode electrode layer including aluminum, and a third anode electrode layer including titanium nitride.

According to some embodiments of the present disclosure, in a method of manufacturing a display device, the method includes: forming a pixel-circuit layer on a substrate; patterning an anode electrode on the pixel-circuit layer; forming a base pixel defining layer over the anode electrode; forming a sacrificial layer on the base pixel defining layer; forming a sacrificial layer opening by removing at least a portion of the sacrificial layer; manufacturing a pre-etched sacrificial layer by removing at least a portion of the sacrificial layer; forming a pixel defining groove by removing at least a portion of the base pixel defining layer; and patterning a pixel defining layer including a pixel defining opening exposing the anode electrode by removing a portion of the base pixel defining layer including the pixel defining groove.

According to some embodiments, the method may further include forming, on the sacrificial layer, a photoresist layer forming a photoresist opening exposing at least a portion of the sacrificial layer. According to some embodiments, a position of the photoresist opening may correspond to a position of the sacrificial layer opening.

According to some embodiments, the forming of the pre-etched sacrificial layer may include performing an etch-back process on the sacrificial layer. According to some embodiments, the pre-etched sacrificial layer may have a thickness thinner than a thickness of the sacrificial layer.

According to some embodiments, the sacrificial layer and the base pixel defining layer may include different materials.

According to some embodiments, the sacrificial layer may include silicon oxide (SiOₓ). According to some embodiments, the base pixel defining layer may include a layer including silicon nitride (SiNₓ).

According to some embodiments, in the forming of the pixel defining groove, a thickness of the pre-etched sacrificial layer may be decreased.

According to some embodiments, a position of the pixel defining groove may correspond to a position of the pixel defining opening.

According to some embodiments, the method may further include removing the pre-etched sacrificial layer after the forming of the pixel defining groove.

According to some embodiments, the pixel defining layer may include a rounded upper surface. According to some embodiments, in the patterning of the pixel defining layer, the rounded upper surface of the pixel defining layer may be manufactured.

According to some embodiments, the method may further include forming a sacrificial protective layer including a metal material on the anode electrode. According to some embodiments, the forming of the base pixel defining layer may include entirely covering, by the base pixel defining layer, a top surface of the sacrificial protective layer.

According to some embodiments, the patterning of the pixel defining layer may include: removing at least a portion of the sacrificial protective layer; and exposing at least a portion of the anode electrode.

According to some embodiments, the patterning of the pixel defining layer may include forming, by the pixel defining layer, an undercut structure.

### BRIEF DESCRIPTION OF THE DRAWINGS

FIG. 1 is a schematic plan view illustrating a display device according to some embodiments of the present disclosure.

FIG. 2 is an exploded perspective view illustrating a portion of the display device shown in FIG. 1 according to some embodiments.

FIG. 3 is a plan view illustrating aspects of a pixel shown in FIG. 2 according to some embodiments.

FIG. 4 is a plan view illustrating aspects of a pixel shown in FIG. 2 according to some embodiments.

FIG. 5 is a plan view illustrating aspects of a pixel shown in FIG. 2 according to some embodiments.

FIG. 6 is a sectional view taken along the line I-I′ shown in FIG. 3.

FIG. 7 is a sectional view illustrating aspects of a light emitting structure included in any one of first to third light emitting elements shown in FIG. 6 according to some embodiments.

FIG. 8 is a sectional view illustrating aspects of the light emitting structure included in the one of the first to third light emitting elements shown in FIG. 6 according to some embodiments.

FIGS. 9 and 10 are schematic sectional views illustrating aspects of a display device according to some embodiments of the present disclosure.

FIGS. 11 to 18 are schematic sectional views illustrating process steps of a method of manufacturing a display device according to some embodiments of the present disclosure.

FIG. 19 is a block diagram illustrating aspects of a display system according to some embodiments.

FIG. 20 is a perspective view illustrating an application example of the display system shown in FIG. 19 according to some embodiments.

FIG. 21 is a view illustrating a head-mounted display device shown in FIG. 20, which is worn by a user, according to some embodiments.

### DETAILED DESCRIPTION

Aspects of some embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey the scope of the example embodiments to those skilled in the art.

In the drawing figures, dimensions may be exaggerated for clarity of illustration. It will be understood that when an element is referred to as being “between” two elements, it can be the only element between the two elements, or one or more intervening elements may also be present. Like reference numerals refer to like elements throughout.

Hereinafter, aspects of some embodiments of the present disclosure will be described in more detail with reference to the accompanying drawings. In the description below, only a necessary part to understand an operation according to the present disclosure is described and the descriptions of other parts are omitted in order not to unnecessarily obscure subject matters of the present disclosure. In addition, the present disclosure is not limited to embodiments described herein, but may be embodied in various different forms. Rather, embodiments described herein are provided to thoroughly and completely describe the disclosed contents and to sufficiently transfer the ideas of the disclosure to a person of ordinary skill in the art.

In the entire specification, when an element is referred to as being “connected” or “coupled” to another element, it can be directly connected or coupled to the another element or be indirectly connected or coupled to the another element with one or more intervening elements interposed therebetween. The technical terms used herein are used only for the purpose of illustrating a specific embodiment and not intended to limit the embodiments. It will be understood that when a component “includes” an element, unless there is another opposite description thereto, it should be understood that the component does not exclude another element but may further include another element. It will be understood that for the purposes of this disclosure, “at least one of X, Y, and Z” can be construed as X only, Y only, Z only, or any combination of two or more items X, Y, and Z (e.g., XYZ, XY, YZ, XZ). Similarly, for the purposes of this disclosure, “at least one selected from the group consisting of X, Y, and Z” can be construed as X only, Y only, Z only, or any combination of two or more items X, Y, and Z (e.g., XYZ, XY, YZ, XZ).

It will be understood that, although the terms “first”, “second,” etc. may be used herein to describe various elements, these elements should not be limited by these terms. These terms are only used to distinguish one element from another element. Thus, a “first” element discussed below could also be termed a “second” element without departing from the teachings of the present disclosure.

Spatially relative terms, such as “below,” “above,” and the like, may be used herein for ease of description to describe the relationship of one element to another element, as illustrated in the figures. It will be understood that the spatially relative terms, as well as the illustrated configurations, are intended to encompass different orientations of the apparatus in use or operation in addition to the orientations described herein and depicted in the figures. For example, if the apparatus in the figures is turned over, elements described as “below” or “beneath” other elements or features would then be oriented “above” the other elements or features. Thus, the term, “above,” may encompass both an orientation of above and below. The apparatus may be otherwise oriented (e.g., rotated 90 degrees or at other orientations) and the spatially relative descriptors used herein interpreted accordingly.

In addition, the embodiments of the disclosure are described here with reference to schematic diagrams of ideal embodiments (and an intermediate structure) of the present disclosure, so that changes in a shape as shown due to, for example, manufacturing technology and/or a tolerance may be expected. Therefore, the embodiments of the present disclosure shall not be limited to the specific shapes of a region shown here, but include shape deviations caused by, for example, the manufacturing technology. The regions shown in the drawings are schematic in nature, and the shapes thereof do not represent the actual shapes of the regions of the device, and do not limit the scope of the disclosure.

The present disclosure generally relates to a display device and a method of manufacturing a display device. Hereinafter, a display device and a method of manufacturing a display device according to some embodiments of the present disclosure will be described in more detail with reference to the accompanying drawings.

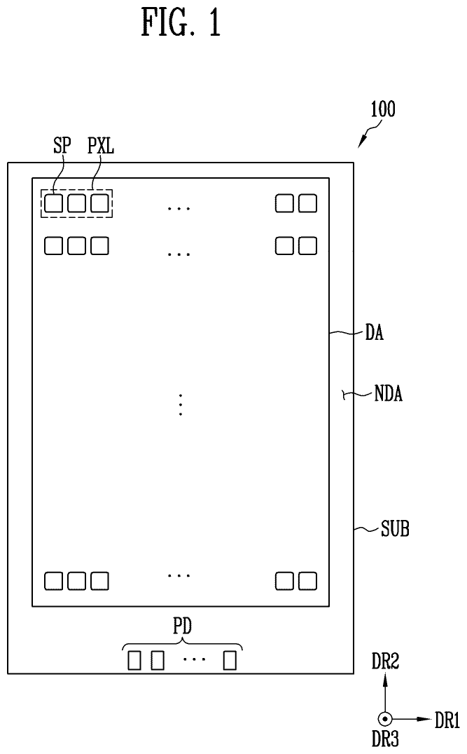

FIG. 1 is a schematic plan view illustrating a display device according to some embodiments of the present disclosure.

Referring to FIG. 1, the display device 100 according to some embodiments of the present disclosure may be configured to emit light.

The display device 100 may include a display area DA and a non-display area NDA. The display device 100 may display images through the display area DA. The non-display area NDA may be located at the periphery (e.g., outside a footprint) of the display area DA.

The display device 100 may include a substrate SUB, sub-pixels SP, and pads PD.

When the display device 100 is used as a display screen of a Head Mounted Display (HMD) device, a Virtual Reality (VR) device, a Mixed Reality (MR) device, an Augmented Reality (AR) device, and the like, the display device 100 may be located very close to eyes of a user. The sub-pixels SP having a relatively high degree of integration may be required. In order to increase the integration of the sub-pixels SP, the substrate SUB may be provided as a silicon substrate. The sub-pixels SP and/or the display device 100 may be formed on the substrate SUB as the silicon substrate. The display device 100 formed on the substrate SUB as the silicon substrate may be designated as an OLED on Silicon (OLEDoS) display device.

The sub-pixels SP may be located in the display area DA on the substrate SUB. The sub-pixels SP may be arranged in a matrix form along a first direction DR1 and a second direction DR2 intersecting the first direction DR1. However, embodiments are not limited thereto. For example, the sub-pixels SP may be arranged in a zigzag form along the first direction DR1 and the second direction DR2. For example, the sub-pixels SP may be located in a PENTILE™ form. The first direction DR1 may be a row direction, and the second direction DR2 may be a column direction.

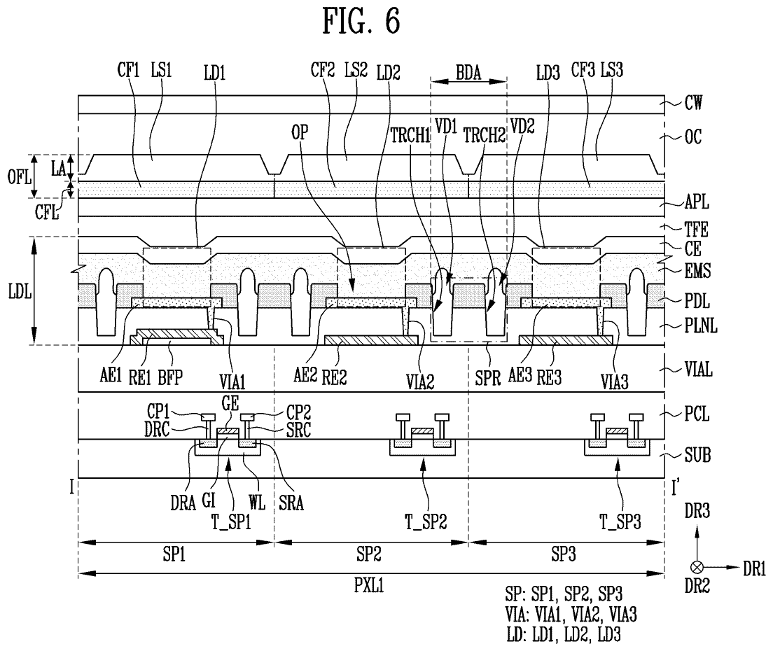

Each of the sub-pixels SP may include at least one light emitting element LD (see FIG. 6) configured to generate light. Accordingly, each of the sub-pixels SP may generate light of a specific color such as red, green, blue, cyan, magenta or yellow. Two or more sub-pixels SP among the sub-pixels SP may constitute a pixel PXL. For example, three sub-pixels SP may constitute a pixel PXL as shown in FIG. 1.

Hereinafter, embodiments in which the sub-pixels SP includes a first sub-pixel SP1 providing light of a first color (e.g., red), a second sub-pixel SP2 providing light of a second color (e.g., green), and a third sub-pixel SP3 providing light of a third color (e.g., blue) will be mainly described.

According to some embodiments, the first sub-pixel SP1 is a red pixel and may provide light in a wavelength band of 600 nm to 750 nm. The second sub-pixel SP2 is a green pixel and may provide light in a wavelength band of 480 nm to 560 nm. The third sub-pixel SP3 is a blue pixel and may provide light in a wavelength band of 370 nm to 460 nm.

A component for controlling the sub-pixels SP may be located in the non-display area NDA on the substrate SUB. For example, lines connected to the sub-pixels SP (e.g., gate lines, data lines, and the like, which are used to drive the sub-pixels SP) may be located in the non-display area NDA. In addition, a gate driver, a data driver, a voltage generator, a controller, a temperature sensor, and the like, which are used to acquire driving signals supplied to the sub-pixels SP, may be integrated in the non-display area NDA of the display device 100. However, embodiments according to the present disclosure are not limited thereto.

The pads PD may be located in the non-display area NDA on the substrate SUB. The pads PD may be electrically connected to the sub-pixels SP through the lines. For example, the pads PD may be connected to the sub-pixels SP through the data lines.

The pads PD may interface components in the display area DA and the non-display area NDA with other components of the display device 100. According to some embodiments, voltages and signals, which are necessary for operations of components included in the display device 100, may be provided from a driver integrated circuit through the pads PD. For example, the data lines may be electrically connected to the driver integrated circuit through the pads PD. For example, power voltages for driving the sub-pixels SP may be received from the driver integrated circuit through the pads PD. For example, a gate control signal for controlling the gate driver may be transmitted to the gate driver from the driver integrated circuit through the pads PD.

According to some embodiments, a circuit board may be electrically connected to the pads PD, using a conductive adhesive member such as an anisotropic conductive film. The circuit board may be a Flexible Printed Circuit Board (FPCB) or a flexible film, which has a flexible material. The driver integrated circuit DIC may be mounted on the circuit board to be electrically connected to the pads PD.

According to some embodiments, the display area DA may have various shapes. The display area DA may have a closed-loop shape including linear sides and/or curved sides. For example, the display area DA may have shapes such as a polygon, a circle, a semicircle, and an ellipse.

According to some embodiments, the display device 100 may have a flat display surface. In other embodiments, the display device 100 may at least partially have a round display surface. According to some embodiments, the display device 100 may be bendable, foldable or rollable. The display device 100 and/or the substrate SUB may include materials having flexibility.

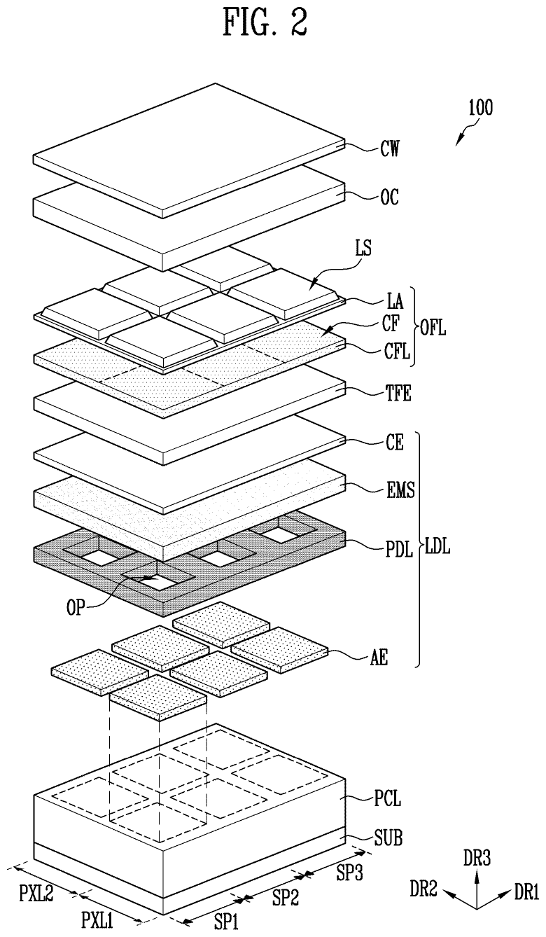

FIG. 2 is an exploded perspective view illustrating a portion of the display device shown in FIG. 1. In FIG. 2, for clear and brief description, a portion of the display device 100, which corresponds to two pixels PXL1 and PXL2 among the pixels PXL shown in FIG. 1, may be schematically illustrated. A portion of the display device 100, which corresponds to the other pixels, may also be configured identically.

Referring to FIGS. 1 and 2, each of first and second pixels PXL1 and PXL2 may include first to third sub-pixels SP1, SP2, and SP3. However, embodiments are not limited thereto. For example, each of the first and second pixels PXL1 and PXL2 may include four sub-pixels or include two sub-pixels.

In FIG. 2, it may be illustrated that the first to third sub-pixels SP1 to SP3 may have quadrangular shapes and have the same size when viewed in a third direction DR3 (e.g., when viewed in a plan view) intersecting the first and second directions DR1 and DR2. However, embodiments according to the present disclosure are not limited thereto. The first to third sub-pixels SP1 to SP3 may be modified to have various shapes.

The display device 100 may include a substrate SUB, a pixel-circuit layer PCL, a light-emitting-element layer LDL, an encapsulation layer TFE, an optical functional layer OFL, an overcoat layer OC, and a cover window CW.

According to some embodiments, the substrate SUB may include a silicon wafer substrate formed using a semiconductor process. The substrate SUB may include a semiconductor material suitable for forming circuit elements. For example, the semiconductor material may include silicon, germanium, and/or silicon-germanium. The substrate SUB may be provided from a bulk wafer, an epitaxial layer, a Silicon On Insulator (SOI) layer, a Semiconductor On Insulator (SeOI) layer, or the like. In other embodiments, the substrate SUB may include a glass substrate. According to some embodiments, the substrate SUB may include a polyimide (PI) substrate.

The pixel-circuit layer PCL may be located on the substrate SUB. The substrate SUB and/or the pixel-circuit layer PCL may include insulating layers and conductive patterns located between the insulating layers. The conductive patterns of the pixel-circuit layer PCL may serve as at least some of circuit elements, lines, and the like. The conductive patterns may include copper, but embodiments of the present disclosure are not limited thereto.

The circuit elements may include a sub-pixel circuit of each of the first to third sub-pixels SP1, SP2, and SP3. The sub-pixel circuit may include transistors and one or more capacitors. Each transistor may include a semiconductor portion including a source region, a drain region, and a channel region, and a gate electrode overlapping with the semiconductor portion. According to some embodiments, when the substrate SUB is provided as a silicon substrate, the semiconductor portion may be included in the substrate SUB, and the gate electrode may be included as a conductive pattern of the pixel-circuit layer PCL in the pixel-circuit layer PCL. According to some embodiments, when the substrate SUB is provided as a glass substrate or a PI substrate, the semiconductor portion and the gate electrode may be included in the pixel-circuit layer PCL. Each capacitor may include electrodes spaced apart from each other. For example, each capacitor may include electrodes spaced apart from each other on a plane defined by the first and second directions DR1 and DR2. For example, each capacitor may include electrodes spaced apart from each other in the third direction DR3 with an insulating layer interposed therebetween.

The lines of the pixel-circuit layer PCL may include signal lines, e.g., a gate line, an emission control line, a data line, and the like, which are connected to each of the first to third sub-pixels SP1, SP2, and SP3.

The light-emitting-element layer LDL may include anode electrodes AE, a pixel defining layer PDL, a light emitting structure EMS, and a cathode electrode CE.

The anode electrodes AE may be located on the pixel-circuit layer PCL. The anode electrodes AE may be in contact with the circuit elements of the pixel-circuit layer PCL. The anode electrodes AE may include an opaque conductive material capable of reflecting light. However, embodiments according to the present disclosure are not limited thereto.

The pixel defining layer PDL may be located on the anode electrodes AE. The pixel defining layer PDL may include an opening OP exposing a portion of each of the anode electrodes AE. The opening OP of the pixel defining layer PDL may be understood as an emission area corresponding to each of the first to third sub-pixels SP1 to SP3.

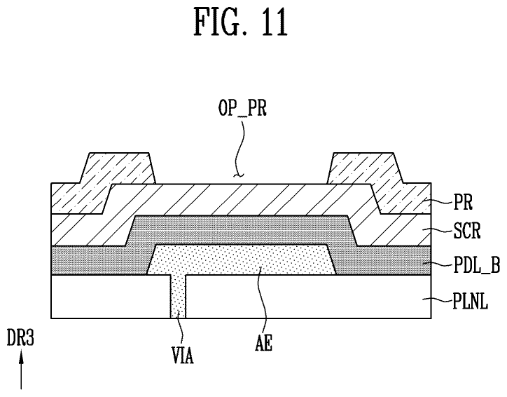

According to some embodiments, the pixel defining layer PDL may include an inorganic material. For example, the pixel defining layer PDL may include at least one of silicon oxide (SiOₓ), or silicon nitride (SiNₓ). According to some embodiments, the pixel defining layer PDL may include a layer including a material different from a material of a sacrificial layer SCR (see FIG. 11) used in a process of manufacturing the display device 100. For example, at least a portion of the pixel defining layer PDL (e.g., at least one layer included in the pixel defining layer PDL) may include silicon nitride (SiNₓ), and the sacrificial layer SCR may include silicon oxide (SiOₓ). According to some embodiments, the pixel defining layer PDL may include an organic material. However, the material of the pixel defining layer PDL is not limited thereto.

According to some embodiments, the pixel defining layer PDL may have a single-layer structure. Alternatively, according to some embodiments, the pixel defining layer PDL may have a multi-layer structure. Hereinafter, for convenience of description, embodiments in which the pixel defining layer PDL has the single-layer structure will be mainly described.

The light emitting structure EMS may be located on the anode electrodes AE exposed by the openings OP of the pixel defining layer PDL. The light emitting structure EMS may include a light generation layer configured to generate light, an electron transport layer configured to transport electrons, a hole transport layer configured to transport holes, and the like.

According to some embodiments, the light emitting structure EMS fills the openings OP of the pixel defining layer PDL, and may be entirely located on the top of the pixel defining layer PDL. In other words, the light emitting structure EMS may extend throughout the first to third sub-pixels SP1 to SP3. At least some of the layers in the light emitting structure EMS may be cut or bent at boundaries between the first to third sub-pixels SP1 to SP3. However, embodiments according to the present disclosure are not limited thereto. For example, portions of the light emitting structure EMS, which correspond to the first to third sub-pixels SP1 to SP3, may be separated from each other, and each of the portions may be located in the opening OP of the pixel defining layer PDL.

The cathode electrode CE may be located on the light emitting structure EMS. The cathode electrode CE may extend throughout the first to third sub-pixels SP1 to SP3. As such, the cathode electrode CE may be provided as a common electrode for the first to third sub-pixels SP1 to SP3.

The cathode electrode CE may be a thin metal layer having a thickness to a degree to which light emitted from the light emitting structure EMS can be transmitted therethrough. The cathode electrode CE may be formed of a metal material to have a relatively thin thickness or be formed of a transparent conductive material. According to some embodiments, the cathode electrode CE may include at least one of various transparent conductive materials including indium tin oxide, indium zinc oxide, indium tin zinc oxide, aluminum zinc oxide, gallium zinc oxide, zinc tin oxide, or gallium tin oxide. In other embodiments, the cathode electrode CE may include at least one of silver (Ag), magnesium (Mg), and/or any combination or mixture thereof. However, the material of the cathode electrode CE is not limited thereto.

It may be understood that any one of the anode electrodes AE, a portion of the light emitting structure EMS, which overlaps therewith, and a portion of the cathode electrode CE, which overlaps therewith, constitute a light emitting element LD (see FIG. 6). In other words, each of light emitting elements LD of the first to third sub-pixels SP1 to SP3 may include an anode electrode AE, a portion of the light emitting structure EMS, which overlaps therewith, and a portion of the cathode electrode CE, which overlaps therewith. In each of the first to third sub-pixels SP1 to SP3, holes injected from the anode electrode AE and electrons injected from the cathode electrode CE may be transported into the light emitting structure EMS to form excitons, and light may be generated when the excitons are changed from an excited state to a ground state. A luminance of the light may be determined according to an amount of current flowing through the light emitting layer. A wavelength range of the generated light may be determined according to a configuration of the light emitting layer.

The encapsulation layer TFE may be located over the cathode electrode CE. The encapsulation layer TFE may cover the light-emitting-element layer LDL and/or the pixel-circuit layer PCL. The encapsulation layer TFE may be configured to prevent or reduce instances of oxygen and/or moisture and/or other contaminants infiltrating into the light-emitting-element layer LDL. According to some embodiments, the encapsulation layer TFE may include a structure in which at least one inorganic layer and at least one organic layer are alternately stacked. For example, the inorganic layer may include silicon nitride, silicon oxide, silicon oxynitride (SiOₓN_{y}), or the like. For example, the organic layer may include an organic insulating material such as acrylic resin, epoxy resin, phenolic resin, polyamide resin, polyimide resin, unsaturated polyester resin, polyphenylene resin, polyphenylenesulfide resin, or benzocyclobutene (BCB) resin. However, the materials of the organic layer and the inorganic layer of the encapsulation layer TFE are not limited thereto.

In order to improve encapsulation efficiency of the encapsulation layer TFE, the encapsulation layer TFE may further include a thin film including aluminum oxide (AlOₓ). The thin film including the aluminum oxide may be located on a top surface of the encapsulation layer TFE, which faces the optical functional layer OFL, and/or a bottom surface of the encapsulation layer TFE, which faces the light-emitting-element layer LDL.

The thin film including the aluminum oxide may be formed through an Atomic Layer Deposition (ALD) process. However, embodiments according to the present disclosure are not limited thereto. The encapsulation layer TFE may further include a thin film formed of at least one of various materials suitable for the improvement of the encapsulation efficiency.

The optical functional layer OFL may be located on the encapsulation layer TFE. The optical functional layer OFL may include a color filter layer CFL and a lens array LA.

The color filter layer CFL may be located between the encapsulation layer TFE and the lens array LA. The color filter layer CFL may be configured filter light emitted from the light emitting structure EMS, thereby selectively outputting light of a wavelength range or a color, which corresponds to each sub-pixel SP. The color filter layer CFL may include color filters CF respectively corresponding to the first to third sub-pixels SP1 to SP3. Each of the color filters CF may allow light having a wavelength range corresponding to a corresponding sub-pixel SP to pass therethrough. For example, a color filter corresponding to the first sub-pixel SP1 may allow light of a red color to pass therethrough, a color filter corresponding to the second sub-pixel SP2 may allow light of a green color to pass therethrough, and a color filter corresponding to the third sub-pixel SP3 may allow light of a blue color to pass therethrough. According to light emitted from the light emitting structure EMS in each sub-pixel SP, at least some of the color filters CF may be omitted.

The lens array LA may be located on the color filter layer CFL. The lens array LA may include lenses LS respectively corresponding to the first to third sub-pixels SP1 to SP3. Each of the lenses LS may output light emitted from the light emitting structure EMS along an intended path, thereby improving light emission efficiency. The lens array LA may have a relatively high refractive index. For example, the lens array LA may have a refractive index higher than a refractive index of the overcoat layer OC. According to some embodiments, the lenses LS may include an organic material. According to some embodiments, the lenses LS may include an acryl-based material. However, the material of the lenses LS is not limited thereto.

According to some embodiments, as compared with the opening OP of the pixel defining layer PDL, at least some of the color filters CF of the color filter layer CFL and at least some of the lenses LS of the lens array LA may be shifted in a direction parallel to a plane defined by the first and second directions DR1 and DR2. Specifically, in a central area of the display area DA, the center of the color filter CF and the center of the lens LS may be aligned or overlap with the center of a corresponding opening OP of the pixel defining layer PDL when viewed in the third direction DR3. For example, in the central area of the display area DA, the opening OP of the pixel defining layer PDL may completely overlap with a corresponding color filter CF of the color filter layer CFL and a corresponding lens LS of the lens array LA. In an area adjacent to the non-display area NDA of the display area DA, the center of the color filter CF and the center of the lens LS may be shifted in a plane direction from the center of the opening OP of the pixel defining layer PDL when viewed in the third direction DR3 (e.g., in a plan view). For example, in an area adjacent to the non-display area NDA of the display area DA, the opening OP of the pixel defining layer PDL may partially overlap with a corresponding color filter CF of the color filter layer CFL and a corresponding lens LS of the lens array LA. Accordingly, at the center of the display area DA, light emitted from the light emitting structure EMS can be efficiently output in a normal direction of the display surface. At a portion adjacent to the non-display area NDA of the display area DA, light emitted from the light emitting structure EMS can be efficiently output in a direction inclined by an angle (e.g., a set or predetermined angle) with respect to the normal direction.

The overcoat layer OC may be located over the lens array LA. The overcoat layer OC may cover the optical functional layer OFL, the encapsulation layer TFE, the light emitting structure EMS, and/or the pixel-circuit layer PCL. The overcoat layer OC may include various materials suitable for protecting lower layers thereof from foreign matters such as dust and moisture. For example, the overcoat layer OC may include at least one of an inorganic insulating layer or an organic insulating layer. For example, the overcoat layer OC may include epoxy, but embodiments are not limited thereto. The overcoat layer OC may have a refractive index lower than a refractive index of the lens array LA.

The cover window CW may be located on the overcoat layer OC. The cover window CW may be configured to protect lower layers thereof. The cover window CW may have a refractive index higher than the refractive index of the overcoat layer OC. The cover window CW may include glass, but embodiments are not limited thereto. For example, the cover window CW may be an encapsulation glass configured to protect components located on the bottom thereof. In other embodiments, the cover window CW may be omitted.

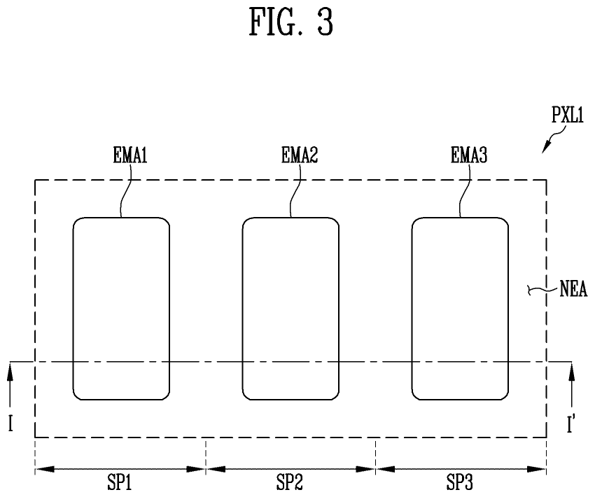

FIG. 3 is a plan view illustrating aspects of any one of the pixels shown in FIG. 2 according to some embodiments. In FIG. 3, for clear and brief description, the first pixel PXL1 among the first and second pixels PXL1 and PXL2 shown in FIG. 2 is schematically illustrated. The other pixels may be configured identically to the first pixel PXL1.

Referring to FIGS. 2 and 3, the first pixel PXL1 may include a first sub-pixel SP1, a second sub-pixel SP2, and a third sub-pixel SP3, which are arranged in the first direction DR1.

The first sub-pixel SP1 may include a first emission area EMA1 and a non-emission area NEA at the periphery of the first emission area EMA1. The second sub-pixel SP2 may include a second emission area EMA2 and the non-emission area at the periphery NEA of the second emission area EMA2. The third sub-pixel SP3 may include a third emission area EMA3 and the non-emission area NEA at the periphery of the third emission area EMA3.

The first emission area EMA1 may be an area in which light is emitted from a portion (e.g., a first light emitting element LD1) of the light emitting structure EMS, which corresponds to the first sub-pixel SP1. The second emission area EMA2 may be an area in which light is emitted from a portion (e.g., a second light emitting element LD2) of the light emitting structure EMS, which corresponds to the second sub-pixel SP2. The third emission area EMA3 may be an area in which light is emitted from a portion (e.g., a third light emitting element LD3) of the light emitting structure EMS, which corresponds to the third sub-pixel SP3. As described with reference to FIG. 2, each emission area may be understood as an opening OP of the pixel defining layer PDL, which corresponds to each of the first sub-pixel SP1, the second sub-pixel SP2, and the third sub-pixel SP3.

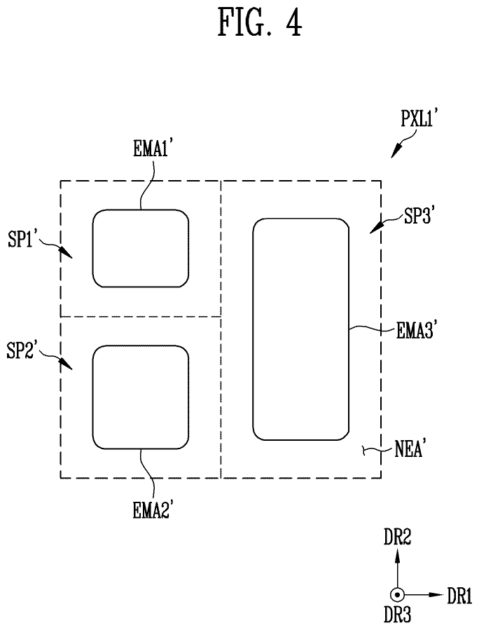

FIG. 4 is a plan view illustrating aspects of the one of the pixels shown in FIG. 2 according to some embodiments.

Referring to FIG. 4, a first pixel PXL1′ may include first to third sub-pixels SP1′ to SP3′.

The first sub-pixel SP1′ may include a first emission area EMA1′ and a non-emission area NEA′ at the periphery of the first emission area EMA1′. The second sub-pixel SP2′ may include a second emission area EMA2′ and the non-emission area NEA′ at the periphery of the second emission area EMA2′. The third sub-pixel SP3′ may include a third emission area EMA3′ and the non-emission area NEA′ at the periphery of the third emission area EMA3′.

The first sub-pixel SP1′ and the second sub-pixel SP2′ may be arranged in the second direction DR2. The third sub-pixel SP3′ may be located in the first direction DR1 with respect to each of the first and second sub-pixels SP1′ and SP2′.

The second sub-pixel SP2′ may have an area greater than an area of the first sub-pixel SP1′, and the third sub-pixel SP3′ may have an area greater than the area of the second sub-pixel SP2′. Accordingly, the second emission area EMA2′ may have an area greater than an area of the first emission area EMA1′, and the third emission area EMA3′ may have an area greater than the area of the second emission area EMA2′. However, embodiments are not limited thereto. For example, the first and second sub-pixels SP1′ and SP2′ may substantially have the same area, and the third sub-pixel SP3′ may have an area greater than the area of each of the first and second sub-pixels SP1′ and SP2′. As such, the areas of the first to third sub-pixels SP1′ to SP3′ may be variously modified according to some embodiments.

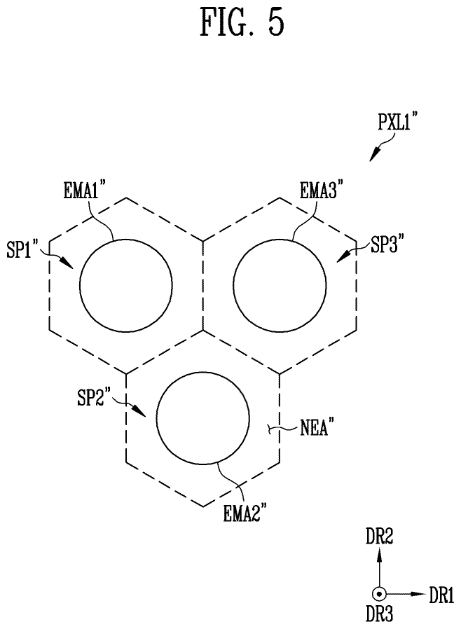

FIG. 5 is a plan view illustrating aspects of the one of the pixels shown in FIG. 2 according to some embodiments.

Referring to FIG. 5, a first sub-pixel SP1″ may include a first emission area EMA1″ and a non-emission area NEA″ at the periphery of the first emission area EMA1″. A second sub-pixel SP2″ may include a second emission area EMA2″ and the non-emission area NEA″ at the periphery of the second emission area EMA2″. A third sub-pixel SP3″ may include a third emission area EMA3″ and the non-emission area NEA″ at the periphery of the third emission area EMA3″.

The first to third sub-pixels SP1″ to SP3″ may have polygonal shapes when viewed in the third direction DR3. For example, the shapes of the first to third sub-pixels SP1″ to SP3″ may be hexagonal shapes as shown in FIG. 2.

The first to third emission areas EMA1″ to EMA3″ may have circular shapes when viewed in the third direction DR3. However, embodiments are not limited thereto. For example, each of the first to third emission areas EMA1″ to EMA3″ may have a polygonal shape.

The first and third sub-pixels SP1″ and SP3″ may be arranged in the first direction DR1. The second sub-pixel SP2″ may be arranged in a direction (or diagonal direction) inclined by an acute angle, based on the second direction DR2, with respect to the first sub-pixel SP1″.

The arrangements of the sub-pixels, which are shown in FIGS. 3 to 5, are merely illustrative, and embodiments according to the present disclosure are not limited thereto. Each pixel may include two or more sub-pixels, and the sub-pixels may be arranged in various manners. Each of the sub-pixels may have various shapes, and each of emission areas EMA1, EMA2, and EMA3 of the sub-pixel may have various shapes.

FIG. 6 is a sectional view taken along the line I-I′ shown in FIG. 3. FIG. 6 is a schematic sectional view illustrating the display device 100 according to some embodiments of the present disclosure.

Referring to FIG. 6, a substrate SUB and a pixel-circuit layer PCL located on the substrate SUB are provided.

The substrate SUB may include a silicon wafer substrate formed using a semiconductor process. For example, the substrate SUB may include silicon, germanium, and/or silicon-germanium.

The pixel circuit layer PCL may be located on the substrate SUB. The substrate SUB and the pixel-circuit layer PCL may include circuit elements of each of first to third sub-pixels SP1 to SP3. For example, the substrate SUB and the pixel-circuit layer PCL may include a transistor T_SP1 of the first sub-pixel SP1, a transistor T_SP2 of the second sub-pixel SP2, and a transistor T_SP3 of the third sub-pixel SP3. The transistor T_SP1 of the first sub-pixel SP1 may be any one of transistors included in a sub-pixel circuit of the first sub-pixel SP1, the transistor T_SP2 of the second sub-pixel SP2 may be any one of transistors included in a sub-pixel circuit of the second sub-pixel SP2, and the transistor T_SP3 of the third sub-pixel SP3 may be any one of transistors included in a sub-pixel circuit of the third sub-pixel SP3. In FIG. 6, for clear and brief description, one of the transistors of each sub-pixel is illustrated, and the other circuit elements of the sub-pixel circuit are omitted.

The transistor T_SP1 of the first sub-pixel SP1 may include a source region SRA, a drain region DRA, and a gate electrode GE.

The source region SRA and the drain region DRA may be located in the substrate SUB. A well WL formed through an ion implantation process may be located in the substrate SUB, and the source region SRA and the drain region DRA may be located in the well WL to be spaced apart from each other. A region between the source region SRA and the drain region DRA in the well WL may be defined as a channel region.

The gate electrode GE may overlap with the channel region between the source region SRA and the drain region DRA, and be located in the pixel-circuit layer PCL. The gate electrode GE may be spaced apart from the well WL or the channel region by an insulating material such as a gate insulating layer GI. The gate electrode GE may include a conductive material.

A plurality of layers included in the pixel-circuit layer PCL may include insulating layers and conductive patterns located between the insulating layers, and the conductive patterns may include first and second conductive patterns CP1 and CP2. The first conductive pattern CP1 may be electrically connected to the drain region DRA through a drain connection portion DRC penetrating one or more insulating layers. The second conductive pattern CP2 may be electrically connected to the source region SRA through a source connection portion SRC penetrating one or more insulating layers.

As the gate electrode GE and the first and second electrode patterns CP1 and CP2 are connected to other circuit elements and/or lines, the transistor T_SP1 of the first sub-pixel SP1 may be provided as any one of the transistors of the first sub-pixel SP1.

Each of the transistor T_SP2 of the second sub-pixel SP2 and the transistor T_SP3 of the third sub-pixel SP3 may be configured identically to the transistor T_SP1 of the first sub-pixel SP1.

As such, the substrate SUB and/or the pixel-circuit layer PCL may include circuit elements of each of the first to third sub-pixels SP1 to SP3.

A via layer VIAL may be located on the pixel-circuit layer PCL. The via layer VIAL covers the pixel-circuit layer PCL, and may have an entirely flat surface. The via layer VIAL may be configured to planarize step differences on the pixel-circuit layer PCL. The via layer VIAL may include at least one of silicon oxide (SiOₓ), silicon nitride (SiNₓ), or silicon carbon nitride (SiCN), but embodiments according to the present disclosure are not limited thereto.

A light-emitting-element layer LDL may be located on the via layer VIAL. The light-emitting-element layer LDL may include first to third reflective electrodes RE1 to RE3, a planarization layer PLNL, first to third anode electrodes AE1 to AE3, a pixel defining layer PDL, a light emitting structure EMS, and a cathode electrode CE.

On the via layer VIAL, the first to third reflective electrodes RE1 to RE3 are respectively located in the first to third sub-pixels SP1 to SP3. Each of the first to third reflective electrodes RE1 to RE3 may be in contact with a circuit element located in the pixel-circuit layer PCL through a via penetrating the via layer VIAL.

The first to third reflective electrodes RE1 to RE3 may serve as full mirrors which reflect light emitted from the light emitting structure EMS toward a display surface (or a cover window CW). The first to third reflective electrodes RE1 to RE3 may include a metal material suitable for reflecting light. The first to third reflective electrodes RE1 to RE3 may include at least one of aluminum (Al), silver (Ag), magnesium (Mg), platinum (Pt), palladium (Pd), gold (Au), nickel (Ni), neodymium (Nd), iridium (Ir), chromium (Cr), titanium (Ti), and/or alloys of two or more materials selected therefrom, but embodiments according to the present disclosure are not limited thereto.

According to some embodiments, a connection electrode may be located on the bottom of each of the first to third reflective electrodes RE1 to RE3. The connection electrode may improve an electrical connection characteristic between a corresponding reflective electrode and a circuit element of the pixel-circuit layer PCL. The connection electrode may have a multi-layer structure. The multi-layer structure may include titanium (Ti), titanium nitride (TiN), tantalum nitride (TaN), and the like, but embodiments are not limited thereto. According to some embodiments, a corresponding reflective electrode may be located between multiple layers of the connection electrode.

A buffer pattern BFP may be located on the bottom of at least one of the first to third reflective electrodes RE1 to RE3. The buffer pattern BFP may include an inorganic material such as silicon carbon nitride, but embodiments according to the present disclosure are not limited thereto. As the buffer pattern BFP is formed, a height of the corresponding reflective electrode in the third direction DR3 may be controlled. For example, the buffer pattern BFP may be located between the first reflective electrode RE1 and the via layer VIAL, to control a height of the first reflective electrode RE1.

The first to third reflective electrodes RE1 to RE3 may serve as full mirrors, and the cathode electrode CE may serve as a half mirror. Light emitted from a light emitting layer of the light emitting structure EMS may be amplified by at least partially reciprocating between a corresponding reflective electrode and the cathode electrode CE, and the amplified light may be output through the cathode electrode CE. As such, a distance between each reflective electrode and the cathode electrode CE may be understood as a resonance distance of light emitted from the light emitting layer of the corresponding light emitting structure EMS.

By the buffer pattern BFP, the first sub-pixel SP1 may have a resonance distance shorter than a resonance distance of another sub-pixel. Light in a specific wavelength range (e.g., a red color) may be effectively and efficiently amplified by the adjusted resonance distance. Accordingly, the first sub-pixel SP1 can effectively and efficiently output light of the corresponding wavelength range.

In FIG. 6, it is illustrated the buffer pattern BFP is provided to the first sub-pixel SP1 and is not provided to the second and third sub-pixels SP2 and SP3. However, embodiments according to the present disclosure are not limited thereto. The buffer pattern may be provided even in at least one of the second or third sub-pixels SP2 or SP3, to adjust a resonance distance of the at least one of the second or third sub-pixels SP2 or SP3. For example, the first to third sub-pixels SP1 to SP3 may respectively correspond to red, green, and blue. A distance between the first reflective electrode RE1 and the cathode electrode CE may be shorter than a distance between the second reflective electrode RE2 and the cathode electrode CE, and the distance between the second reflective electrode RE2 and the cathode electrode CE may be shorter than a distance between the third reflective electrode RE3 and the cathode electrode CE.

The planarization layer PLNL may be located on the via layer VIAL and the first to third reflective electrodes RE1 to RE3 to planarize step differences between the first to third reflective electrodes RE1 to RE3. The planarization layer PLNL entirely covers the first to third reflective electrodes RE1 to RE3 and the via layer VIAL, and may have a flat surface. According to some embodiments, the planarization layer PLNL may be omitted.

The first to third anode electrodes AE1 to AE3 respectively overlapping with the first to third reflective electrodes RE1 to RE3 may be located on the planarization layer PLNL. The first to third anode electrodes AE1 to AE3 may have shapes similar to the shapes of the first to third emission areas EMA1 to EMA3 shown in FIG. 3 when viewed in the third direction DR3. The first to third anode electrodes AE1 to AE3 may be connected to the first to third reflective electrodes RE1 to RE3, respectively. The first anode electrode AE1 may be connected to the first reflective electrode RE1 through a first via VIA1 penetrating the planarization layer PLNL. The second anode electrode AE2 may be connected to the second reflective electrode RE2 through a second via VIA2 penetrating the planarization layer PLNL. The third anode electrode AE3 may be connected to the third reflective electrode RE3 through a third via VIA3 penetrating the planarization layer PLNL. The first via VIA1, the second via VIA2 and the third via VIA3 may be included in a via VIA

According to some embodiments, the first to third anode electrodes AE1 to AE3 may include at least one of transparent conductive materials such as indium tin oxide (ITO), indium zinc oxide (IZO), zinc oxide (ZnO), indium gallium zinc oxide (IGZO), or indium tin zinc oxide (ITZO). However, the material of the first to third anode electrodes AE1 to AE3 is not limited thereto. For example, the first to third anode electrodes AE1 to AE3 may include titanium nitride, and include titanium (Ti) or aluminum (Al).

According to some embodiments, insulating layers for adjusting the height of one or more of the first to third anode electrodes AE1 to AE3 may be further provided. The insulating layers may be located between one or more of the first to third anode electrodes AE1 to AE3 and corresponding reflective electrodes. The planarization layer PLNL and/or the buffer pattern BFP may be omitted. For example, the first to third sub-pixels SP1 to SP3 may correspond to red, green, and blue, respectively. A distance between the first anode electrode AE1 and the cathode electrode CE may be shorter than a distance between the second anode electrode AE2 and the cathode electrode CE, and the distance between the second anode electrode AE2 and the cathode electrode CE may be shorter than a distance between the third anode electrode AE3 and the cathode electrode CE. The pixel defining layer PDL may be located on portions of the first to third anode electrodes AE1 to AE3 and the planarization layer PLNL. The pixel defining layer PDL may include an opening OP exposing a portion of each of the first to third anode electrodes AE1 to AE3. The opening OP of the pixel defining layer PDL may define an emission area of each of the first to third sub-pixels SP1 to SP3. As such, the pixel defining layer PDL may define the first to third emission areas EMA1 to EMA3 while being located in the non-emission area NEA.

According to some embodiments, the pixel defining layer PDL may include a plurality of inorganic insulating layers. Each of the plurality of inorganic insulating layers may include at least one of silicon oxide (SiOₓ) or silicon nitride (SiNₓ). For example, the pixel defining layer PDL may include first to third inorganic insulating layers which are sequentially stacked, and each of the first to third inorganic insulating layers may include silicon nitride, silicon oxide, and silicon oxynitride. However, embodiments are not limited thereto. The first to third inorganic insulating layers may have a step-shaped section in an area adjacent to the opening OP.

A separator SPR may be provided in a boundary area BDA between sub-pixels adjacent to each other. In other words, the separator SPR may be provided in each of boundary areas between the sub-pixels SP shown in FIG. 1.

The separator SPR may cause a discontinuity in the light emitting structure EMS in the boundary area BDA. For example, the light emitting structure EMS may be cut or bent by the separator SPR in the boundary area BDA.

The separator SPR may be provided in or on the pixel defining layer PDL. The pixel defining layer PDL may include one or more trenches TRCH1 and TRCH2 as the separator SPR. According to some embodiments, as shown in FIG. 6, the one or more trenches TRCH1 and TRCH2 may penetrate the pixel defining layer PDL, and partially penetrate the planarization layer PLNL. In other embodiments, the one or more trenches TRCH1 and TRCH2 may penetrate the pixel defining layer PDL and the planarization layer PLNL, and partially penetrate the via layer VIAL. In still other embodiments, the one or more trenches TRCH1 and TRCH2 may at least partially penetrate the planarization layer PLNL and/or the via layer VIAL, and at least a portion of the pixel defining layer PDL may be located in the one or more trenches TRCH1 and TRCH2.

In FIG. 6, it is illustrated that two trenches TRCH1 and TRCH2 are provided in the boundary area BDA. However, embodiments are not limited thereto. For example, the pixel defining layer PDL may include a trench in the boundary area BDA. Alternatively, the pixel defining layer PDL may include three or more trenches in the boundary area BDA.

Due to the first and second trenches TRCH1 and TRCH2, discontinuities such as a first void VD1 and a second void VD2 may be formed in the light emitting structure EMS in the boundary area BDA. Some of a plurality of layers stacked in the light emitting structure EMS may be cut or bent by the first and second voids VD1 and VD2. For example, at least one charge generation layer included in the light emitting structure EMS may be cut by the first and second voids VD1 and VD2. As such, due to the first and second trenches TRCH1 and TRCH2, portions of the light emitting structure EMS, included in the first to third sub-pixels SP1 to SP3, may be at least partially separated from each other.

In FIG. 6, it is illustrated that the first and second voids VD1 and VD2 are formed in the light emitting structure EMS in the boundary area BDA. However, this is merely illustrative, and embodiments are not limited thereto. For example, a concave-shaped valley may be formed in the light emitting structure EMS in the boundary area BDA. The discontinuities formed in the light emitting structure EMS may be variously changed according to shapes of the first and second trenches TRCH1 and TRCH2.

According to some embodiments, the light emitting structure EMS may be formed through a process such as vacuum deposition or inkjet printing. The same materials as the light emitting structure EMS may be located on bottom surfaces adjacent to the via layer VIAL among the first and second trenches TRCH1 and TRCH2.

The separator SPR may be variously modified such that the light emitting structure EMS can have a discontinuity in the boundary area BDA. According to some embodiments, inorganic insulating patterns additionally stacked on the pixel defining layer PDL without the first and second trenches TRCH1 and TRCH2 may be provided in the boundary area BDA. A width of an inorganic insulating pattern at an uppermost portion among the additionally stacked inorganic insulating patterns may be greater than a width of an inorganic insulating pattern located immediately below the inorganic insulating pattern at the uppermost portion. For example, in the boundary area BDA, first to third inorganic insulating patterns are sequentially stacked from the pixel defining layer PDL, and the third inorganic insulating pattern at the uppermost portion may have a width greater than a width of the second inorganic insulating layer. For example, the pixel defining layer PDL may have a section having a “T” shape or an “I” shape in the boundary area BDA. According to the shape of the pixel defining layer PDL, the plurality of layers included in the light emitting structure EMS may be partially cut or bent in the boundary area BDA.

The light emitting structure EMS may be located on the anode electrodes AE exposed by the openings OP of the pixel defining layer PDL. The light emitting structure EMS may fill the openings OP of the pixel defining layer PDL, and be entirely arranged throughout the first to third sub-pixels SP1 to SP3. As described above, the light emitting structure EMS may be partially cut or bent in the boundary area BDA by the separator SPR. Accordingly, in an operation of the display device 100, the magnitude of current leaked from each of the first to third sub-pixels SP1 to SP3 to a sub-pixel adjacent thereto through the layers included in the light emitting structure EMS may be decreased. Thus, first to third light emitting elements LD1 to LD3 can operate with a relatively high reliability.

The cathode electrode CE may be arranged over the light emitting structure EMS. The cathode electrode CE may be commonly provided in the first to third sub-pixels SP1 to SP3. The cathode electrode CE may serve as a half mirror which allow light emitted from the light emitting structure EMS to be partially transmitted therethrough and to be partially reflected therefrom.

The first anode electrode AE1, a portion of the light emitting structure EMS, which overlaps with the first anode electrode AE1, and a portion of the cathode electrode CE, which overlaps with the first anode electrode AE1, may constitute the first light emitting element LD1. The second anode electrode AE2, a portion of the light emitting structure EMS, which overlaps with the second anode electrode AE2, and a portion of the cathode electrode CE, which overlaps with the second anode electrode AE2, may constitute the second light emitting element LD2. The third anode electrode AE3, a portion of the light emitting structure EMS, which overlaps with the third anode electrode AE3, and a portion of the cathode electrode CE, which overlaps with the third anode electrode AE3, may constitute the third light emitting element LD3.

An encapsulation layer TFE may be arranged over the cathode electrode CE. The encapsulation layer TFE may prevent or reduce instances of oxygen and/or moisture and/or other contaminants infiltrating into the light-emitting-element layer LDL.

An optical functional layer OFL may be located on the encapsulation layer TFE. According to some embodiments, the optical functional layer OFL may be attached to the encapsulation layer TFE through an adhesive layer APL. For example, the optical functional layer OFL may be separately manufactured to be attached to the encapsulation layer TFE through the adhesive layer APL. The adhesive layer APL may further perform a function of protecting lower layers including the encapsulation layer TFE.

The optical functional layer OFL may include a color filter layer CFL and a lens array LA. The color filter layer CFL may include first to third color filters CF1 to CF3 respectively corresponding to the first to third sub-pixels SP1 to SP3. The first to third color filters CF1 to CF3 may allow lights having different wavelength ranges to pass therethrough. For example, the first to third color filters CF1 to CF3 may allow light of red, green, and blue colors to pass therethrough, respectively.

According to some embodiments, the first to third color filters CF1 to CF3 may partially overlap with each other in the boundary area BDA. In other embodiments, the first to third color filters CF1 to CF3 may be spaced apart from each other, and a black matrix may be provided between the first to third color filters CF1 to CF3.

The lens array LA may be located on the color filter layer CFL. The lens array LA may include first to third lenses LS1 to LS3 respectively corresponding to the first to third sub-pixels SP1 to SP3. The first to third lenses LS1 to LS3 may respectively output lights emitted from the first to third light emitting elements LD1 to LD3 along intended paths, thereby improving light emission efficiency.

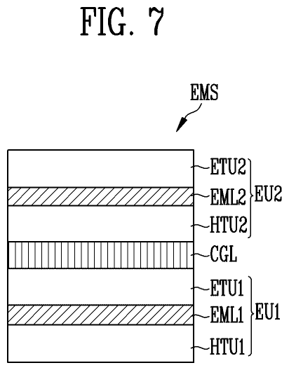

FIG. 7 is a sectional view illustrating aspects of a light emitting structure included in any one of the first to third light emitting elements shown in FIG. 6 according to some embodiments.

Referring to FIG. 7, the light emitting structure EMS may have a tandem structure in which first and second light emitting parts EU1 and EU2 are stacked. The light emitting structure EMS may be configured substantially identically in each of the first to third light emitting elements LD1 to LD3 shown in FIG. 6.

Each of the first and second light emitting parts EU1 and EU2 may include at least one light emitting layer generating light according to an applied current. The first light emitting part EU1 may include a first light emitting layer EML1, a first electron transport part ETU1, and a first hole transport part HTU1. The first light emitting layer EML1 may be located between the first electron transport part ETU1 and the first hole transport part HTU1. The second light emitting part EU2 may include a second light emitting layer EML2, a second electron transport part ETU2, and a second hole transport part HTU2. The second light emitting layer EML2 may be located between the second electron transport part ETU2 and the second hole transport part HTU2.

Each of the first and second hole transport parts HTU1 and HTU2 may include at least one of a hole injection layer and a hole transport layer. Each of the first and second hole transport parts HTU1 and HTU2 may further include a hole buffer layer, an electron blocking layer, and the like, if necessary. The first and second hole transport parts HTU1 and HTU2 may have the same configuration or have different configurations.

Each of the first and second electron transport parts ETU1 and ETU2 may include at least one of an electron injection layer or an electron transport layer. Each of the first and second electron transport parts ETU1 and ETU2 may further include an electron buffer layer, a hole blocking layer, and the like, if necessary. The first and second electron transport parts ETU1 and ETU2 may have the same configuration or have different configurations.

A connection layer, which may be provided in the form of a charge generation layer CGL, may be located between the first light emitting part EU1 and the second light emitting part EU2 to connect the first light emitting part EU1 and the second light emitting part EU2 to each other. According to some embodiments, the charge generation layer CGL may have a stacked structure of a p-dopant layer and an n-dopant layer. For example, the p-dopant layer may include a p-type dopant such as HAT-CN, TCNQ or NDP-9, and the n-dopant layer may include an alkali metal, an alkali earth metal, a lanthanide-based metal, or any combination thereof. However, embodiments are not limited thereto.

According to some embodiments, the first light emitting layer EML1 and the second light emitting layer EML2 may generate lights of different colors. Lights respectively emitted from the first light emitting layer EML1 and the second light emitting layer EML2 may be mixed together, to be viewed as white light. For example, the first light emitting layer EML1 may generate light of a blue color, and the second light emitting layer EML2 may generate light of a yellow color. According to some embodiments, the second light emitting layer EML2 may include a structure in which a first sub-light emitting layer configured to generate light of a red color and a second sub-light emitting layer configured to generate light of a green color are stacked. The light of the red color and the light of the green color may be mixed together to provide the light of the yellow color. An intermediate layer configured to perform a function of transporting holes and/or a function of blocking transportation of electrodes may be further located between the first and second sub-light emitting layers.

In other embodiments, the first light emitting layer EML1 and the second light emitting layer EML2 may generate light of the same color.

The light emitting structure EMS may be formed through a process such as vacuum deposition or inkjet printing, but embodiments are not limited thereto.

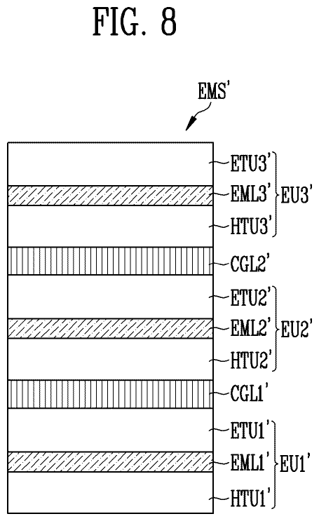

FIG. 8 is a sectional view illustrating aspects of the light emitting structure included in the one of the first to third light emitting elements shown in FIG. 6 according to some embodiments.

Referring to FIG. 8, a light emitting structure EMS′ may a tandem structure in which first to third light emitting parts EU1′ to EU3′ are stacked. The light emitting structure EMS′ may be configured substantially identically in each of the first to third light emitting elements LD1 to LD3 shown in FIG. 6.

Each of the first to third light emitting parts EU1′ to EU3′ may include a light emitting layer generating light according to an applied current. The first light emitting part EU1′ may include a first light emitting layer EML1′, a first electron transport part ETU1′ and a first hole transport part HTU1′. The first light emitting layer EML1′ may be located between the first electron transport part ETU1′ and the first hole transport part HTU1′. The second light emitting part EU2′ may include a second light emitting layer EML2′, a second electron transport part ETU2′, and a second hole transport part HTU2′. The second light emitting layer EML2′ may be located between the second electron transport part ETU2′ and the second hole transport part HTU2′. The third light emitting part EU3′ may include a third light emitting layer EML3′, a third electron transport part ETU3′, and a third hole transport part HTU3′. The third light emitting layer EML3′ may be located between the third electron transport part ETU3′ and the third hole transport part HTU3′.

Each of the first to third hole transport parts HTU1′ to HTU3′ may include at least one of a hole injection layer or a hole transport layer, and further include a hole buffer layer, and an electron blocking layer, and the like, if necessary. The first to third hole transport parts HTU1′ to HTU3′ may have the same configuration or have different configurations.

Each of the first to third electron transport parts ETU1′ to ETU3′ may include at least one of an electron injection layer or an electron transport layer, and further include an electron buffer layer, a hole blocking layer, and the like, if necessary. The first to third electron transport parts ETU1′ to ETU3′ may have the same configuration or have different configurations.

A first charge generation layer CGL1′ may be located between the first light emitting part EU1′ and the second light emitting part EU2′. A second charge generation layer CGL2′ may be located between the second light emitting part EU2′ and the third light emitting part EU3′.

According to some embodiments, the first to third light emitting layers EML1′ to EML3′ may generate lights of different colors. Lights respectively emitted from the first to third light emitting layers EML1′ to EML3′ may be mixed together, to be viewed as white light. For example, the first light emitting layer EML1′ may generate light of a blue color, the second light emitting layer EML2′ may generate light of a green color, and the third light emitting layer EML3′ may generate light of a red color.

In other embodiments, light emitting layers of at least two of the first to third light emitting layers EML1′ to EML3′ may generate light of the same color.

Unlike as shown in FIGS. 7 and 8, the light emitting structure EMS shown in FIG. 6 may include one light emitting part in each of the first to third light emitting elements LD1 to LD3. The light emitting part included in each of the first to third light emitting elements LD1 to LD3 may be configured to emit lights of different colors. For example, the light emitting part of the first light emitting element LD1 may emit light of a red color, the light emitting part of the second light emitting element LD2 may emit light of a green color, and the light emitting part of the third light emitting element LD3 may emit light of a blue color. Unlike as shown in FIG. 6, light emitting structures of the first to third sub-pixels SP1 to SP3 may be separated from each other, and each of the light emitting structures may be located in the opening OP of the pixel defining layer PDL. At least some of the color filters CF1 to CF3 may be omitted.

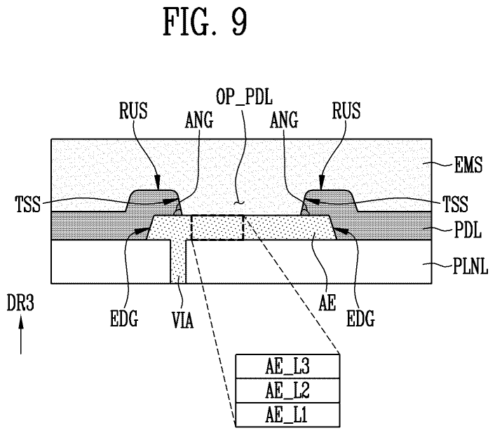

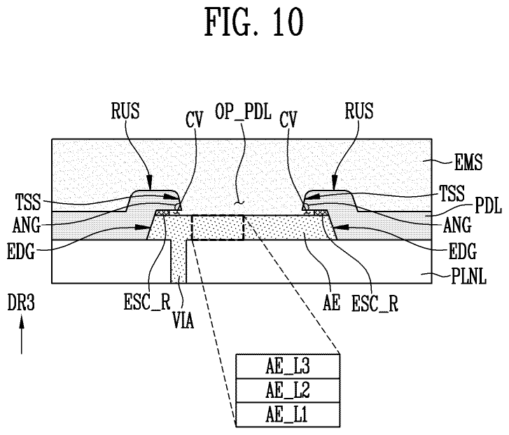

Hereinafter, a pixel defining layer PDL according to some embodiments of the present disclosure and components adjacent thereto will be described in more detail with reference to FIGS. 9 and 10. In FIGS. 9 and 10, portions overlapping with those described above will be briefly described or will not be repeated.

FIGS. 9 and 10 are schematic sectional views illustrating a display device according to some embodiments of the present disclosure. FIGS. 9 and 10 are sectional views illustrating a partial area of a sub-pixel SP, and schematically illustrate a pixel defining layer PDL according to some embodiments of the present disclosure and components adjacent thereto. For example, FIGS. 9 and 10 schematically illustrate the pixel defining layer PDL, an anode electrode AE, a planarization layer PLNL, and a light emitting structure EMS. FIGS. 9 and 10 may illustrate any one of first to third sub-pixels SP1 to SP3.

FIG. 9 may be a schematic sectional view of a display device 100 according to some embodiments of the present disclosure.

Referring to FIG. 9, an anode electrode AE, a pixel defining layer PDL, and a light emitting structure EMS may be located on a base (e.g., a planarization layer PLNL).

The anode electrode AE may be electrically connected to other components of the pixel-circuit layer PCL through a via. The anode electrode AE may be electrically connected to at least a portion of the light emitting structure EMS so as to form a sub-pixel SP. For example, at least a portion of the anode electrode AE may be exposed by the pixel defining layer PDL. The at least a portion of the anode electrode AE, which is exposed by the pixel defining layer PDL, may be electrically connected to the light emitting structure EMS.

According to some embodiments, the anode electrode AE may include a multi-layer structure. For example, the anode electrode AE may include a first anode electrode layer AE_L1, a second anode electrode layer AE_L2, and a third anode electrode layer AE_L3. According to some embodiments, the first anode electrode layer AE_L1 may include titanium (Ti). The second anode electrode layer AE_L2 may include aluminum (Al). The third anode electrode layer AE_L3 may include titanium nitride (TiN). However, the present disclosure is not limited thereto.

The pixel defining layer PDL may cover at least a portion of the anode electrode AE. For example, the pixel defining layer PDL may cover each of both end portions of the anode electrode AE.

The pixel defining layer PDL may expose at least a portion of the anode electrode AE. For example, the pixel defining layer PDL may form (or include) a pixel defining opening OP_PDL (i.e., the opening OP described above), and the anode electrode AE may be exposed in the pixel defining opening OP_PDL.

The pixel defining layer PDL may be arranged to least a partial area in which the anode electrode AE is arranged from a partial area of the planarization layer PLNL, in which the anode electrode AE is not located. For example, the pixel defining layer PDL may cover a side surface of the anode electrode AE, cover a top surface of the anode electrode AE, and be in contact with a portion of the planarization layer PLNL.

The pixel defining layer PDL may include a structure capable of preventing or reducing a risk that the cathode electrode CE arranged throughout sub-pixels SP will be cut. For example, the pixel defining layer PDL may include a rounded upper surface RUS including an inclined side surface TSS defined in an area adjacent to an area covering the anode electrode AE.

The rounded upper surface RUS may be defined in an area adjacent to an edge EDG of the anode electrode AE. For example, the rounded upper surface RUS may overlap with the edge EDG of the anode electrode AE in a plan view. The rounded upper surface RUS may be a portion of the pixel defining layer PDL covering the anode electrode AE.

According to some embodiments, the rounded upper surface RUS may be directly adjacent to the light emitting structure EMS. The rounded upper surface RUS may be in contact with the light emitting structure EMS.

The rounded upper surface RUS may include relatively round corners (e.g., rounded corners). For example, the rounded upper surface RUS may not include any angular protrusion corner. The curvature for defining a round portion of the rounded upper surface RUS is nor particularly limited.

The inclined side surface TSS is a portion of the rounded upper surface RUS, and may be a surface of the pixel defining layer PDL, which faces the pixel defining opening OP_PDL. For example, the inclined side surface TSS may be directly adjacent to at least a portion of the light emitting structure EMS, which is located in the pixel defining opening OP_PDL. The inclined side surface TSS may overlap with the anode electrode AE in a plan view.

The inclined side surface TSS may form an angle ANG with the top surface of the anode electrode AE. According to some embodiments, the top surface of the anode electrode AE, which defines the angle ANG, may be parallel to a plane on which the substrate SUB is located. The plane may be a plane defined based on the first direction DR1 and the second direction DR2.

The rounded upper surface RUS may include a relatively round corner portion, and accordingly, the inclined side surface TSS may have a relatively gentle slope. For example, the angle ANG may be 45 degrees or less. The angle ANG may be in a range of 15 degrees to 45 degrees. According to some embodiments, the angle ANG may be in a range of 20 degrees to 45 degrees.

The pixel defining layer PDL may be located between adjacent sub-pixels SP. Therefore, experimentally, when the pixel defining layer PDL includes an angular corner portion, a probability that at least a portion of the cathode electrode CE arranged throughout the sub-pixels SP will be cut may exist. A risk such as a voltage drop may occur.

However, according to some embodiments, the pixel defining layer PDL may include the rounded upper surface RUS, and be provided not to include the angular corner portion. Accordingly, the angle ANG defined by the pixel defining layer PDL can satisfy the above-described numerical range, and the above-described risk can be reduced.

Further, the angle ANG of the pixel defining layer PDL satisfies the above-described numerical range, so that the necessity that the thickness of the pixel defining layer PDL will be manufactured excessively thin may be reduced. Accordingly, the pixel defining layer PDL can be manufactured with one thickness or more, and thus process convenience can be improved. In addition, the separator SPR can be efficiently manufactured inside the pixel defining layer PDL or on the top of the pixel defining layer PDL.

Furthermore, the rounded upper surface RUS of the pixel defining layer PDL according to some embodiments of the present disclosure is manufactured using a sacrificial layer SCR (see FIG. 11), and may be appropriately applied to a display device in which sub-pixels SP are provided relatively adjacent to each other so as to implement high performance. This will be described in more detail later with reference to the drawings from FIG. 11.

FIG. 10 may be a schematic sectional view of a display device 100 according to some embodiments of the present disclosure. The display device 100 according to some embodiments of the present disclosure is different from the display device 100 according to some embodiments of the present disclosure, which is described with reference to FIG. 9, in that the display device 100 according to some embodiments of the present disclosure further include a lower cover layer ESC_R.

Referring to FIG. 10, the display device 100 may further include the lower cover layer ESC_R and a cavity CV, which are located between the pixel defining layer PDL and the anode electrode AE.

According to some embodiments, the lower cover layer ESC_R and the cavity CV may be located on the bottom of the rounded upper surface RUS of the pixel defining layer PDL, and accordingly, the pixel defining layer PDL may form a tip structure in which at least a portion of the pixel defining layer PDL extends in a direction parallel to the plane on which the substrate SUB is located. The pixel defining layer PDL may form an undercut structure.

According to some embodiments, the undercut structure defined by the lower cover layer ESC_R and the cavity CV may cut at least a portion of the light emitting structure EMS.

For example, the light emitting structure EMS may include a plurality of layers, and include a hole injection layer in an area adjacent to the anode electrode AE. Experimentally, in order to prevent or reduce a risk of leakage current between adjacent sub-pixels SP, the hole injection layer in the light emitting structure EMS continuously located between the sub-pixels SP may be cut.

According to some embodiments, the undercut structure defined by the lower cover layer ESC_R and the cavity CV may cut at least a portion of a layer(s) adjacent to the anode electrode AE in the light emitting structure EMS.

Accordingly, a layer which may cause a leakage current, such as the hole injection layer, in the light emitting structure EMS continuously located between adjacent sub-pixels SP can be cut, and a risk such as a leakage current can be reduced in the display device 100 according to some embodiments of the present disclosure.

The lower cover layer ESC_R may be located in an area surrounded by the anode electrode AE and the pixel defining layer PDL. The lower cover layer ESC_R may be directly adjacent to the cavity CV. The lower cover layer ESC_R may be located on the bottom of the rounded upper surface RUS.

The cavity CV may be surrounded by the anode electrode AE, the pixel defining layer PDL, the lower cover layer ESC_R, and the light emitting structure EMS. The cavity CV may be directly adjacent to the anode electrode AE, and expose a portion of the pixel defining layer PDL defining the rounded upper surface RUS.

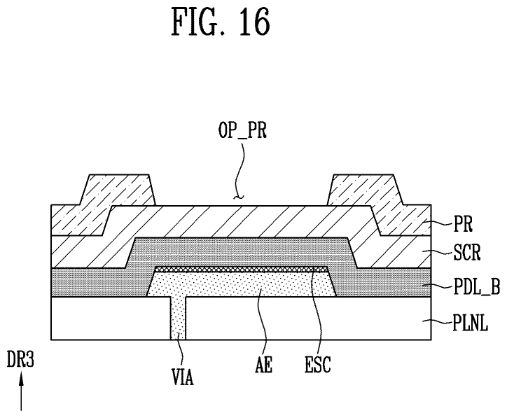

According to some embodiments, the lower cover layer ESC_R may be a residual sacrificial layer manufactured by removing at least a portion of the sacrificial protective layer ESC (see FIG. 16). According to some embodiments, the lower cover layer ESC_R may include a metal material. For example, the lower cover layer ESC_R may include aluminum (Al). However, the present disclosure is not limited thereto.

For example, the lower cover layer ESC_R may be manufactured by removing at least a portion of an etching protective layer for preventing damage of the anode electrode AE when a process of patterning the pixel defining layer PDL is performed.

That is, as the lower cover layer ESC_R is provided, the damage of the anode electrode AE can be prevented or reduced, and a risk such as a leakage current can be reduced as described above.

Hereinafter, a method of manufacturing the display device 100 according to some embodiments of the present disclosure will be described with reference to FIGS. 11 to 18. In FIGS. 11 to 18, portions overlapping with those described above will be briefly described or will not be repeated.

FIGS. 11 to 18 are schematic sectional views illustrating process steps of a method of manufacturing a display device according to some embodiments of the present disclosure.

FIGS. 11 to 15 may illustrate a method of manufacturing the display device 100 according to some embodiments described above with reference to FIG. 9. FIGS. 16 to 18 may illustrate a method of manufacturing the display device 100 according to some embodiments as described above with reference to FIG. 10.

First, the method of manufacturing the display device 100 according to some embodiments as described above with reference to FIG. 9 will be described with reference to FIGS. 11 to 15.

In conjunction with FIG. 6, in order to manufacture the display device according to some embodiments, a pixel-circuit layer PCL may be formed on a substrate SUB, and a planarization layer PLNL may be located on the pixel-circuit layer PCL.

According to some embodiments, a conductive layer and an insulating layer on the substrate SUB may be formed based on a general process for manufacturing a semiconductor device. For example, the conductive layer or the insulating layer on the substrate SUB may be formed through a photolithography process, be etched through various processes (wet etching, dry etching, and the like), and be deposited through various processes (sputtering, chemical vapor deposition, and the like). However, the present disclosure is not necessarily limited to a specific example.

Referring to FIG. 11, an anode electrode AE may be patterned on the planarization layer PLNL, and a via VIA may be formed in the planarization layer PLNL. In addition, a base pixel defining layer PDL_B may be formed (e.g., deposited) over the anode electrode AE, a sacrificial layer SCR may be formed (e.g., deposited) on the base pixel defining layer PDL_B, and a photoresist layer PR may be patterned on the sacrificial layer SCR.

The base pixel defining layer PDL_B may be a layer deposited to be patterned to a pixel defining layer PDL. The base pixel defining layer PDL_B may entirely cover the anode electrode AE.

The sacrificial layer SCR may be located on the base pixel defining layer PDL_B. The sacrificial layer SCR may be directly adjacent to a top surface of the base pixel defining layer PDL_B. The sacrificial layer SCR may entirely cover the base pixel defining layer PDL_B.

The sacrificial layer SCR may be a layer provided to manufacture a rounded upper surface RUS of the pixel defining layer PDL in subsequent processes.

According to some embodiments, the sacrificial layer SCR may include a material different from a material of the base pixel defining layer PDL_B. For example, the base pixel defining layer PDL_B may include a layer including silicon nitride (SiNₓ). The base pixel defining layer PDL_B may include silicon nitride (SiNₓ) in a layer formed at an uppermost portion of the base pixel defining layer PDL_B, and the sacrificial layer SCR may include silicon oxide (SiOₓ).

In subsequent processes, the base pixel defining layer PDL_B may be selectively further etched due to an etch selectivity difference between the sacrificial layer SCR and the base pixel defining layer PDL_B.

The photoresist layer PR may be patterned on the sacrificial layer SCR. The photoresist layer PR may expose at least a portion of the sacrificial layer SCR. The photoresist layer PR may form a photoresist opening OP_PR. According to some embodiments, the photoresist opening OP_PR may correspond to a position of each of a sacrificial opening OP_SCR, a pixel defining groove GR_PDL, and a pixel defining opening OP_PDL, which are manufactured in subsequent processes. For example, the photoresist opening OP_PR, the sacrificial opening OP_SCR, the pixel defining groove GR_PDL, and the pixel defining opening OP_PDL may be defined to overlap with each other in a plan view.

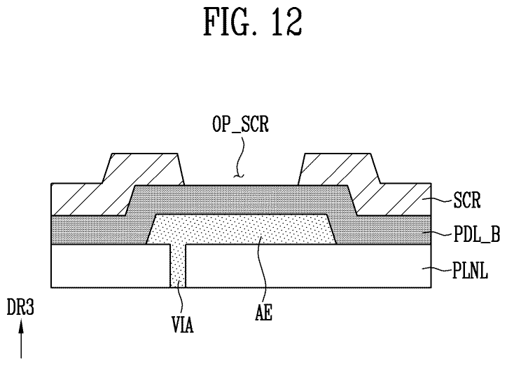

Referring to FIG. 12, at least a portion of the sacrificial layer SCR may be etched using the photoresist layer PR as an etch mask.

In this phase, a portion of the sacrificial layer SCR overlapping with the photoresist opening OP_PR formed by the photoresist layer PR may be etched, and accordingly, the sacrificial layer SCR may form the sacrificial opening OP_SCR. The photoresist layer PR may be removed based on an etch-back process or the like.

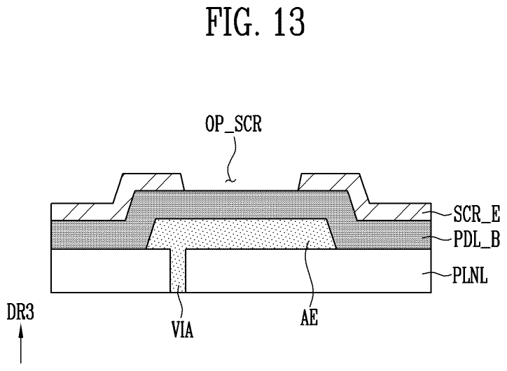

Referring to FIG. 13, at least a portion of the sacrificial layer SCR may be removed such that the thickness of the sacrificial layer SCR is decreased.

In this phase, an etch-back process or the like may be used such that the thickness of the sacrificial layer SCR is decreased. For example, as the thickness of the sacrificial layer SCR is decreased, a pre-etched sacrificial layer SCR_E may be manufactured. The pre-etched sacrificial layer SCR_E may have a thickness thinner than the thickness of the sacrificial layer SCR. The pre-etched sacrificial layer SCR_E may still form the sacrificial opening OP_SCR.

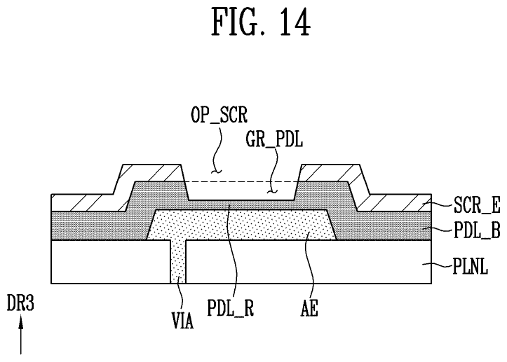

Referring to FIG. 14, at least a portion of the base pixel defining layer PDL_B may be removed. An etching process may be performed on the pre-etched sacrificial layer SCR_E and the base pixel defining layer PDL_B.

In this phase, the thickness of the pre-etched sacrificial layer SCR_E may be decreased. The pixel defining groove GR_PDL may be formed in the base pixel defining layer PDL_B, using the pre-etched sacrificial layer SCR_E as a sacrificial structure. For example, the base pixel defining layer PDL_B and the pre-etched sacrificial layer SCR_E may include different materials, and therefore, amounts of the base pixel defining layer PDL_B and the pre-etched sacrificial layer SCR_E, which are etched under the same etching environment, may be different from each other.

According to some embodiments, the depth of the pixel defining groove GR_PDL may be adjusted by adjusting a thickness difference between the pre-etched sacrificial layer SCR_E and the sacrificial layer SCR in the previous process.

According to some embodiments, because the pixel defining groove GR_PDL is formed using the pre-etched sacrificial layer SCR_E, a position of the pixel defining groove GR_PDL may correspond to a position of the photoresist opening OP_PR.

According to some embodiments, a portion of the base pixel defining layer PDL_B formed on the bottom of the pixel defining groove GR_PDL may be designated as a residual pixel defining layer PDL_R.

After this phase is performed, the pre-etched sacrificial layer SCR_E may be removed based on an etch-back process or the like. Accordingly, the top surface of the base pixel defining layer PDL_B including the pixel defining groove GR_PDL may be exposed.

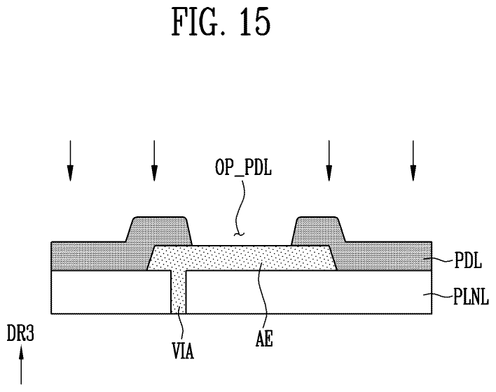

Referring to FIG. 15, the pixel defining layer PDL including the rounded upper surface RUS may be manufactured by removing at least a portion of the base pixel defining layer PDL_B.

In this phase, the pixel defining layer PDL including the rounded upper surface RUS having an angle ANG may be provided by etching at least a portion of an outer surface of the base pixel defining layer PDL_B.

According to some embodiments, the base pixel defining layer PDL_B may be entirely etched, and the residual pixel defining layer PDL_R defined on the bottom of the pixel defining groove PDL_GR may be removed. According to some embodiments, as the residual pixel defining layer PDL_R is removed, the anode electrode AE may be exposed, and an etching process performed in this phase may be completed after the anode electrode AE is exposed.

According to some embodiments, in this phase, the base pixel defining layer PDL_B may be entirely etched before the anode electrode AE is exposed. Therefore, an outer surface of the pixel defining layer PDL may be manufactured not to include any protrusion structure. Accordingly, the pixel defining layer PDL can be manufacture to include the rounded upper surface RUS. That is, according to some embodiments, a rounded structure can be efficiently manufactured in the pixel defining layer PDL even when the distance between sub-pixels SP is very short.

After that, according to some embodiments, the display device 100 according to some embodiments may be provided by forming a light emitting structure EMS and sequentially forming a plurality of structures located on the light emitting structure EMS.

Next, the method of manufacturing the display device 100 according to some embodiments, which is described above with reference to FIG. 10, will be described with reference to FIGS. 16 to 18. The method of manufacturing the display device 100 of FIG. 10 according to some embodiments will be described based on portions different from those of the above-described method of manufacturing the display device 100 of FIG. 9 according to some embodiments.

Referring to FIG. 16, a base pixel defining layer PDL_B, a sacrificial layer SCR, and a photoresist layer PR may be sequentially arranged over an anode electrode AE. Before the base pixel defining layer PDL_B is formed, a sacrificial protective layer ESC may be further formed (e.g., deposited) on the anode electrode AE.

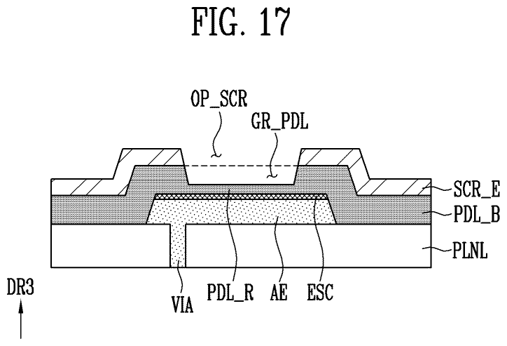

Referring to FIG. 17, similarly to the above-described portions, a sacrificial opening OP_SCR and a pixel defining groove GR_PDL may be formed. According to some embodiments, in this phase, the sacrificial protective layer ESC may be still covered by the base pixel defining layer PDL_B.

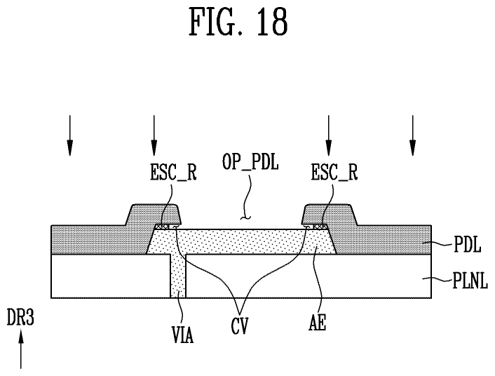

Referring to FIG. 18, as at least a portion of the base pixel defining layer PDL_B is removed, a pixel defining layer PDL including a rounded upper surface RUS may be manufactured, and at least a portion of the sacrificial protective layer ESC may be removed.

According to some embodiments, the sacrificial protective layer ESC may be etched based on a wet etching process. In this phase, as the anode electrode AE is exposed, the pixel defining layer PDL according to some embodiments may be manufactured.

In this phase, a residual pixel defining layer PDL_R may be removed. When the residual pixel defining layer PDL_R is removed, the sacrificial protective layer ESC may serve as a protective layer for the anode electrode AE. When an etching process on the entire base pixel defining layer PDL_B is performed to manufacture the rounded upper surface RUS, the sacrificial protective layer ESC may serve as an etch stopper for the anode electrode AE.

Meanwhile, according to some embodiments, because the sacrificial protective layer ESC and the residual pixel defining layer PDL_R can simultaneously serve as a protective layer for the anode electrode AE, a minimum thickness required in the sacrificial protective layer ESC can be relatively decreased, and accordingly, process cost can be reduced. For example, when only a conductive layer for the etch stopper is simply located on the anode electrode AE, it is necessary for the sacrificial protective layer ESC to have a slightly thick thickness so as to serve as the protective layer. However, in a state in which the residual pixel defining layer PDL_R for providing the rounded upper surface RUS is provided, the sacrificial protective layer ESC may be additionally formed. Therefore, the sacrificial protective layer ESC may have a relatively thin thickness.

In this phase, a cavity CV and a lower cover layer ESC_R may be manufactured. As the cavity CV is formed, the pixel defining layer PDL may form an undercut structure.

After that, similarly to as described above, according to some embodiments, the display device 100 according to some embodiments may be provided by forming a light emitting structure EMS and sequentially forming a plurality of structures located on the light emitting structure EMS.

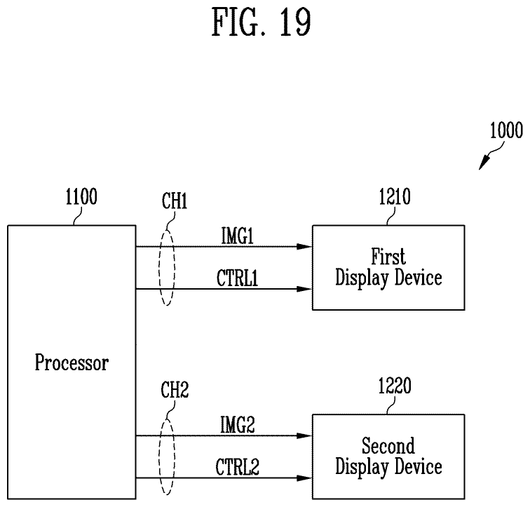

FIG. 19 is a block diagram illustrating aspects of a display system according to some embodiments.

Referring to FIG. 19, a display system 1000 may include a processor 1100 and one or more display devices 1210 and 1220.

The processor 1100 may perform various tasks and various calculations. According to some embodiments, the processor 1100 may include an Application Processor (AP), a Graphics Processing part (GPU), a microprocessor, a Central Processing part (CPU), and the like. The processor 1100 may be connected to other components of the display system 1000 through a bus system to control the components of the display system 1000.

In FIG. 19, it is illustrated that the display system 1000 includes first and second display devices 1210 and 1220. The processor 1100 may be connected to the first display device 1210 through a first channel CH1, and be connected to the second display device 1220 through a second channel CH2.

Through the first channel CH1, the processor 1100 may transmit first image data IMG1 and a first control signal CTRL1 to the first display device 1210. The first display device 1210 may display an image, based on the first image data IMG1 and the first control signal CTRL1. The first display device 1210 may be configured identically to the display device 100 described with reference to FIG. 1.

Through the second channel CH2, the processor 1100 may transmit second image data IMG2 and a second control signal CTRL2 to the second display device 1220. The second display device 1220 may display an image, based on the second image data IMG2 and the second control signal CTRL2. The second display device 1220 may be configured identically to the display device 100 described with reference to FIG. 1.

The display system 1000 may include a computing system for providing an image display function, such as a portable computer, a mobile phone, a smartphone, a tablet personal computer (PC), a smart watch, a watch phone, a portable multimedia player (PMP), a navigation system, or an ultra mobile computer (UMPC). Also, the display system 1000 may include at least one of a head mounted display (HMD) device, a virtual reality (VR) device, a mixed reality (MR) device, or an augmented reality (AR) device.

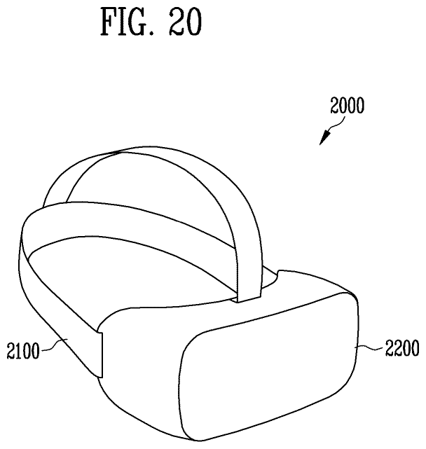

FIG. 20 is a perspective view illustrating an application example of the display system shown in FIG. 19.

Referring to FIG. 20, the display system 1000 shown in FIG. 19 may be applied to a head mounted display device 2000. The head mounted display device 2000 may be a wearable electronic device which can be worn on a head of a user.

The head mounted display device 2000 may include a head mounting band 2100 and a display device accommodating case 2200. The head mounting band 2100 may be connected to the display device accommodating case 2200. The head mounting band 2100 may include a horizontal band and/or a vertical band, used to fix the head mounted display device 2000 to the head of the user. The horizontal band may be configured to surround a side portion of the head of the user, and the vertical band may be configured to surround an upper portion of the head of the user. However, embodiments are not limited thereto. For example, the head mounting band 2100 may be implemented in the form of a glasses frame, a helmet or the like.

The display device accommodating case 2200 may accommodate the first and second display devices 1210 and 1220 shown in FIG. 19. The display device accommodating case 2200 may further accommodate the processor 1100 shown in FIG. 19.

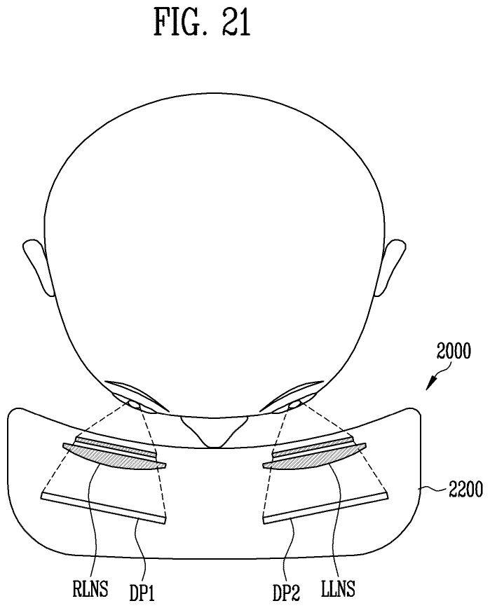

FIG. 21 is a view illustrating a head-mounted display device shown in FIG. 20, which is worn by a user.

Referring to FIG. 21, a first display panel DP1 of the first display device 1210 and a second display panel DP2 of the second display device 1220 may be located in the head mounted display device 2000. The head mounted display device 2000 may further include one or more lenses LLNS and RLNS.

In the display device accommodating case 2200, a right-eye lens RLNS may be located between the first display panel DP1 and a right eye of the user. In the display device accommodating case 2200, a left-eye lens LLNS may be located between the second display panel DP2 and a left eye of the user.

An image output from the first display panel DP1 may be viewed by the right eye of the user through the right-eye lens RLNS. The right-eye lens RLNS may refract light emitted from the first display panel DP1 to face the right eye of the user. The right-eye lens RLNS may perform an optical function for adjusting a viewing distance between the first display panel DP1 and the right eye of the user.

An image output from the second display panel DP2 may be viewed by the left eye of the user through the left-eye lens LLNS. The left-eye lens LLNS may refract light emitted from the second display panel DP2 to face the left eye of the user. The left-eye lens LLNS may perform an optical function for adjusting a viewing distance between the second display panel DP2 and the left eye of the user.

According to some embodiments, each of the right-eye lens RLNS and the left-eye lens LLNS may include an optical lens having a pancake-shaped section. According to some embodiments, each of the right-eye lens RLNS and the left-eye lens LLNS may include a multi-channel lens including sub-areas having different optical characteristics. Each display panel may output images respectively corresponding to the sub-areas of the multi-channel lens, and the output images may be viewed by the user while respectively passing through corresponding sub-areas.

According to some embodiments of the present disclosure, there can be provided a display device and a method of manufacturing a display device, which can provide a detailed cathode electrode structure, thereby relatively reducing a risk such as a voltage drop.

According to some embodiments of the present disclosure, there can be provided a display device and a method of manufacturing a display device, which can improve process convenience.

According to some embodiments of the present disclosure, there can be provided a display device and a method of manufacturing a display device, which can reduce a risk due to a leakage current or the like, thereby improving display quality.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present disclosure as set forth in the following claims, and their equivalents.

What is claimed is:

1. A display device comprising:
a substrate;
a pixel-circuit layer including a pixel circuit on the substrate; and
a light-emitting-element layer on the pixel-circuit layer,
wherein the light-emitting-element layer includes:
an anode electrode;
a pixel defining layer covering at least a portion of the anode electrode, the pixel defining layer forming a pixel defining opening exposing at least a portion of the anode electrode;
a light emitting structure electrically connected to the anode electrode; and
a cathode electrode electrically connected to the light emitting structure,
wherein the pixel defining layer includes a rounded upper surface having a rounded corner, the rounded upper surface including an inclined side surface facing the pixel defining opening, and
wherein an angle between the inclined side surface and a top surface of the anode electrode is in a range of 15 degrees to 45 degrees.

2. The display device of claim 1, further comprising a planarization layer on the pixel-circuit layer,
wherein the pixel defining layer is continuously formed on the planarization layer and the anode electrode, and
wherein the rounded upper surface is defined at a portion of the pixel defining layer covering the anode electrode.

3. The display device of claim 1, wherein the rounded upper surface overlaps with an edge of the anode electrode in a plan view, and contacts the light emitting structure.

4. The display device of claim 1, wherein the pixel defining layer includes an undercut structure.

5. The display device of claim 4, further comprising:
a lower cover layer between the anode electrode and the pixel defining layer; and
a cavity adjacent to the lower cover layer, the cavity being surrounded by the pixel defining layer, the light emitting structure, and the anode electrode.

6. The display device of claim 5, wherein the lower cover layer includes a metal material, and
wherein the cavity is directly adjacent to the light emitting structure.

7. The display device of claim 1, wherein the substrate includes a silicon wafer substrate, and
wherein the light emitting structure includes a hole transport part adjacent to the anode electrode, a light emitting layer on the hole transport part, and an electron transport part on the light emitting layer and being adjacent to the cathode electrode.

8. The display device of claim 1, wherein the anode electrode includes a first anode electrode layer including titanium, a second anode electrode layer including aluminum, and a third anode electrode layer including titanium nitride.

9. A method of manufacturing a display device, the method comprising:
forming a pixel-circuit layer on a substrate;
patterning an anode electrode on the pixel-circuit layer;
forming a base pixel defining layer over the anode electrode;
forming a sacrificial layer on the base pixel defining layer;
forming a sacrificial layer opening by removing at least a portion of the sacrificial layer;
manufacturing a pre-etched sacrificial layer by removing at least a portion of the sacrificial layer;
forming a pixel defining groove by removing at least a portion of the base pixel defining layer; and
patterning a pixel defining layer including a pixel defining opening exposing the anode electrode by removing a portion of the base pixel defining layer including the pixel defining groove.

10. The method of claim 9, further comprising forming, on the sacrificial layer, a photoresist layer forming a photoresist opening exposing at least a portion of the sacrificial layer,
wherein a position of the photoresist opening corresponds to a position of the sacrificial layer opening.

11. The method of claim 9, wherein the forming of the pre-etched sacrificial layer includes performing an etch-back process on the sacrificial layer, and
wherein the pre-etched sacrificial layer has a thickness thinner than a thickness of the sacrificial layer.

12. The method of claim 9, wherein the sacrificial layer and the base pixel defining layer include different materials.

13. The method of claim 12, wherein the sacrificial layer include silicon oxide (SiOₓ), and
wherein the base pixel defining layer includes a layer including silicon nitride (SiNₓ).

14. The method of claim 9, wherein, in the forming of the pixel defining groove, a thickness of the pre-etched sacrificial layer is decreased.

15. The method of claim 14, wherein a position of the pixel defining groove corresponds to a position of the pixel defining opening.

16. The method of claim 9, further comprising removing the pre-etched sacrificial layer after the forming of the pixel defining groove.

17. The method of claim 9, wherein the pixel defining layer includes a rounded upper surface, and
wherein, in the patterning of the pixel defining layer, the rounded upper surface of the pixel defining layer is manufactured.

18. The method of claim 9, further comprising forming a sacrificial protective layer including a metal material on the anode electrode,
wherein the forming of the base pixel defining layer includes entirely covering, by the base pixel defining layer, a top surface of the sacrificial protective layer.

19. The method of claim 18, wherein the patterning of the pixel defining layer includes:
removing at least a portion of the sacrificial protective layer; and
exposing at least a portion of the anode electrode.

20. The method of claim 18, wherein the patterning of the pixel defining layer includes forming, by the pixel defining layer, an undercut structure.
